(19) United States
(12) Patent Application Publication
(10) Pub. No.: US 2007/0216435 A1
(43) Pub. Date: Sep. 20, 2007

(54) Apparatus of measuring characteristics of semiconductor devices

(76) Inventor: Yasuhiko Iguchi, Tokyo (JP)

Correspondence Address: Paul D. Greeley;Ohlandt, Greeley, Ruggiero & Perle, L.L.P., 10th Floor, One Landmark Square, Stamford, CT, 06901-2682, US

(21) Appl. No.: 11/717,961

(22) Filed: Mar. 14, 2007

(30) Foreign Application Priority Data
Mar. 17, 2006 (JP) 2006-075115

(51) Int. Cl. G01R 31/02

(52) U.S. Cl. 324/763

(57) ABSTRACT

An apparatus of measuring characteristics of a plurality of semiconductor devices with a plurality of measurement units is disclosed. The apparatus includes a parallel measurement executability determination section and a plurality of measurement function sections. The parallel measurement executability determination section identifies sets of a semiconductor device and a measurement function, which are able to be measured in parallel based on connection information of the semiconductor devices. The plurality of measurement function sections use a first abstractive name which abstractively identifies the plurality of measurement units for the sets of the measurement functions and the semiconductor device which are able to be measured in parallel by the parallel measurement executability determination section.

### BACKGROUND OF THE INVENTION

1. Field of the Invention

The present invention relates to an apparatus of measuring characteristics of semiconductor devices, for example a test elementary group (TEG) on a semiconductor wafer.

2. Description of the Related Art

A semiconductor parametric test system that has a plurality of source measure units (SMUs) is known as described for example in U.S. Pat. No. 6,304,095 hereinafter referred to as patent document 1. In this semiconductor parameter test system, while a voltage or a current is supplied, the other characteristic is measured. In recent years, semiconductor parametric test systems have been used from basic measurements of voltage or current characteristics of transistors on a wafer in a wafer manufacturing process control to measurements of voltage or current characteristics or and low to high frequency characteristics of various types of devices formed on a wafer.

On the other hand, in the field of general IC testers, as a technology of measuring a plurality of devices (devices under test (DUTs)) in parallel, a technology that uses a pin number assignment table for pins assigned to each device so as to easily assign device pin numbers to test programs simultaneously executed is known as described for example in Japanese Patent Application Laid-Open No. HEI 5-322978 hereinafter referred to as patent document 2.

In the IC tester described in patent document 2, on the assumption that many measurement units operate or are structured according to the same standard or the same specifications, the user needs to have thorough knowledge of the operations of test programs, have obtained combinations of pints for which the test programs securely operate in parallel, and have described these data to a pin group table. Thus, the user needs a great deal of labor.

### SUMMARY OF THE INVENTION

As described above, to accomplish parallel measurements, the user needs a great deal of labor.

The present invention is made from the foregoing point of view. An object of the present invention is to provide an apparatus of measuring characteristics of semiconductor devices that allows characteristics of semiconductor devices to be measured in parallel with ease.

An embodiment of the present invention is an apparatus of measuring characteristics of a plurality of semiconductor devices with a plurality of measurement units. The apparatus includes a parallel measurement executability determination section and a plurality of measurement function sections. The parallel measurement executability determination section identifies sets of a semiconductor device and measurement function, that can be measured in parallel based on connection information of the semiconductor devices. The plurality of measurement function sections use a first abstractive name which abstractively identifies the plurality of measurement units for sets of the measurement function and the semiconductor device which are able to be measured in parallel by the parallel measurement executability determination section.

The apparatus may further include a measurement unit allocation section. The measurement unit allocation section has measurement unit information containing a second abstractive name which abstractively identifies the plurality of measurement units. The measurement unit allocation section allocates an abstractively identified measurement unit for the set of the semiconductor device and the measurement function, which are able to be measured in parallel by the parallel measurement executability determination section, to the measurement function.

In this apparatus, the measurement unit information may correlatively contain the second abstractive name which abstractively identifies the plurality of measurement units and priority levels based on which the plurality of measurement units are allocated to measurement functions. The measurement unit allocation section may allocate the abstractively identified measurement units to the measurement functions in the order of higher priority levels.

In the apparatus, when there are a plurality of measurement units allocatable to the second abstractive name, the priority levels may be assigned lower values in proportion to non-substitutability of the measurement units. When there are a plurality of the second abstractive names that are able to identify a measurement unit, the priority levels of the second abstractive names may be assigned higher values in proportion to non-substitutability of the measurement units.

In the apparatus, the plurality of measurement function sections may operate in parallel. The apparatus may further include a parallel test attribute input section.

The parallel test attribute input section inputs a parallel test attribute. When information which permits a predetermined set of the semiconductor devices to be measured in parallel is input to the parallel attribute input section, the parallel measurement executability determination section determines whether or not the predetermined set is able to be measured in parallel.

The apparatus may further include a parallel test attribute input section. The parallel test attribute input section inputs a parallel test attribute. When information which does not permit a predetermined set of the semiconductor devices to be measured in parallel is input to the parallel attribute input section, the parallel measurement executability determination section determines whether or not the other than the predetermined set is able to be measured in parallel.

The apparatus may further include a parallel test attribute input section. The parallel test attribute input section inputs a parallel test attribute. When information which denotes that a predetermined semiconductor device of the semiconductor devices is not able to be measured in parallel is input to the parallel test attribute input section, the parallel measurement executability determination section determines whether or not other than the predetermined semiconductor device is able to be measured in parallel.

Another embodiment of the present invention is an apparatus of executing a measurement function for a semiconductor device with a plurality of measurement units and measuring characteristics of the semiconductor device. The apparatus includes a measurement allocation section. The measurement allocation section has measurement unit information containing abstractive names which abstractively identify the measurement units. The measurement allocation section allocates abstractively identified measurement units of a set of semiconductor devices and measurement functions to the measurement functions.

According to an embodiment of the present invention, measurement units are abstractively and comprehensively allocated to parallel operations of measurement functions, it is not necessary to perform a special operation for parallel measurements. In addition, since priority levels are assigned to measurement units depending on how they are special (non-substitutable), the executability of parallel measurements can be increased.

These and other objects, features and advantages of the present invention will become more apparent in light of the following detailed description of a best mode embodiment thereof, as illustrated in the accompanying drawings.

### BRIEF DESCRIPTION OF DRAWINGS

FIG. 1 is a block diagram showing the structure of a semiconductor parametric test system according to an embodiment of the present invention;

FIG. 2 is a schematic diagram showing the structure of software of the semiconductor parametric test system shown in FIG. 1;

FIG. 3 shows a table of an example of a test plan;

FIG. 4 is a list showing an example of a program of measurement function Idoff called in the sequence shown in FIG. 3;

FIG. 5 shows a table of hardware members of a tester identified by port numbers and port names;

FIG. 6 shows a table of types and measurement performances of SMUs contained in the tester;

FIG. 7 shows a table of an example of a hardware use definition that is input to a process together with a test plan;

FIG. 8 shows a table of abstractive names and meanings of measurement units used in the hardware use definition;

FIG. 9 is a schematic diagram showing information that a sequence control section contains;

FIG. 10 shows a table of information contained in a sub sequence status table;

FIG. 11 is a flow chart showing an operation of the sequence control section that identifies a not-executed sub sequence to be inspected for executability;

FIG. 12 is a flow chart showing an operation of a sub sequence process;

FIG. 13 shows a table of a test plan that represents a parallel test attribute;

FIG. 14 shows a sub sequence status table for the sequence shown in FIG. 13;

FIG. 15 shows a table of a test plan that describes parallel test attributes and that is used in the case that although devices are designed to be electrically insulated and they mutually interfere due to other than a device structure such as a probe card;

FIG. 16 shows a sub sequence status table for the test plan shown in FIG. 15;

FIG. 17 shows a table of a test plan describing an attribute that denotes that a sub sequence of a device is not able to be executed when a designated sub sequence of a designated device is executed;

FIG. 18 shows a sub sequence status table for the test plan shown in FIG. 17;

FIG. 19 is a sequence chart showing signal handling in the case that a sub sequence is executed;

FIG. 20 shows a hardware management table that is contained in a hardware management section and that is used to manage individual hardware members of the tester;

FIG. 21 shows a real hardware allocation priority table for abstractive hardware type names in the hardware management section;

FIG. 22 is a schematic diagram showing information that the hardware management section contains;

FIG. 23 is a flow chart showing an operation of a process that the hardware management section performs to allocate real hardware members;

FIG. 24 shows an allocatable abstractive hardware table contained in the hardware management section;

FIG. 25 is a schematic diagram showing information that a tester control section contains;

FIG. 26 is a flow chart showing a process that the tester control section performs to correlate port names of measurement functions with hardware members;

FIG. 27 shows an allocated hardware table;

FIG. 28 shows a port name correlation table;

FIG. 29 shows a table representing the structure of a tester used in the case that the semiconductor parametric test system according to an embodiment of the present invention executes sub sequences in parallel;

FIG. 30 shows a table of assumed execution times of measurement functions in sub sequences;

FIG. 31 shows a table of executed results of sub sequences;

FIG. 32 is a schematic diagram showing the structure of a semiconductor parametric test system according to another embodiment of the present invention; and

FIG. 33 is a sequence chart showing the operation of the semiconductor parametric test system according to the embodiment having the structure shown in FIG. 32.

### DESCRIPTION OF PREFERRED EMBODIMENTS

With reference to the accompanying drawings, an embodiment of the present invention will be described.

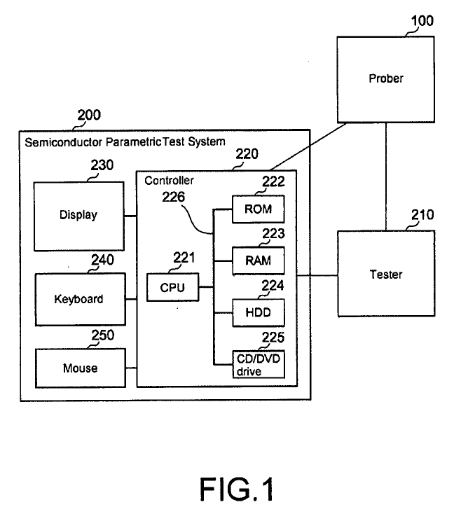

FIG. 1 is a block diagram showing the structure of a semiconductor parametric test system according to an embodiment of the present invention.

In the drawing, reference numeral 100 represents a prober that probes a test elementary group (TEG) on a semiconductor wafer. Reference numeral 200 represents a semiconductor parametric test system that measures characteristics of semiconductor devices of the TEG on the semiconductor wafer. Since a device under test (DUT) is a disposed inside the prober 100, the DUT is not shown in the drawing.

The semiconductor parametric test system 200 is composed of a tester 210, a controller 220 that performs a data process and so forth, a display 230, a keyboard 240, and a mouse 250. The controller 220 is composed of a read only memory (ROM) 222 that stores a program and data, a hard disk drive (HDD) 224, a compact disc (CD)/digital versatile disk (DVD) drive 255, a random access memory (RAM) 223 that is used for example as a working memory for a program that is executed, a central processing unit (CPU) 221 that executes a program, and a bus 226 that electrically connects these units.

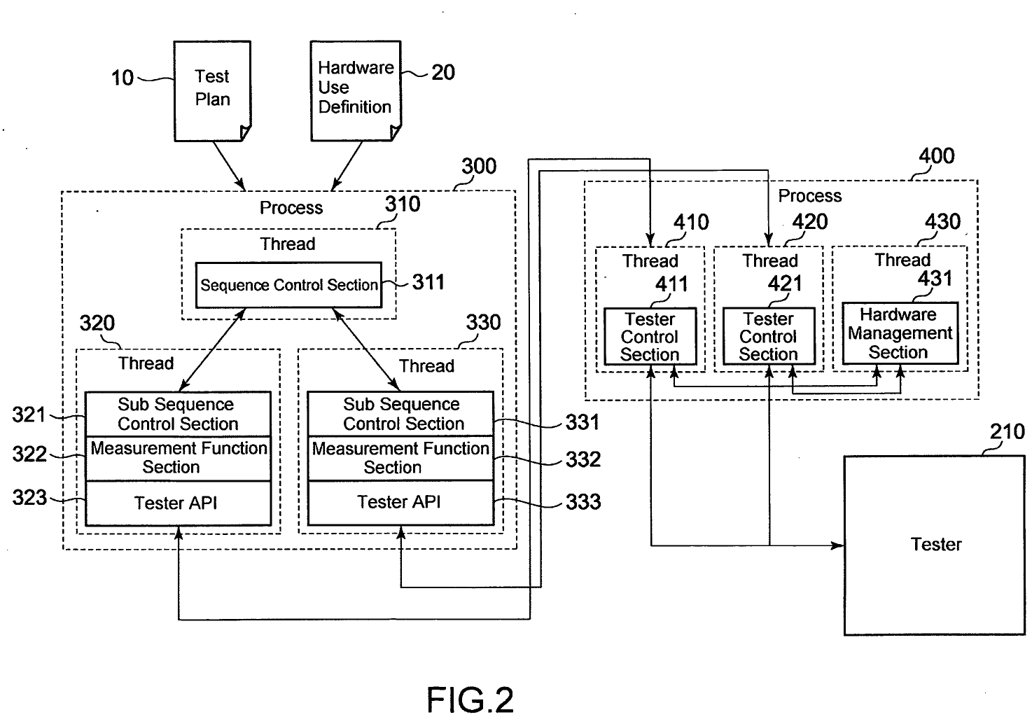

FIG. 2 is a schematic diagram showing the structure of software of the semiconductor parametric test system shown in FIG. 1. As shown in FIG. 2, the test program of the system is composed of two processes 300 and 400. The process 300 is composed of three threads 310, 320, and 330. As the thread 310, a sequence control section 311 operates. As the thread 320, a sub sequencer control section 321, a measurement function section 322, and a tester application program interface (API) 323 operate. In addition, as the thread 330, a sub sequence control section 331, a measurement function section 332, and a tester API 333 operate. Sub sequence control sections, measurement function sections, and tester APIs are structured to operate on two threads. Instead, sub sequence control sections, measurement function sections, and tester APIs may be disposed on three or more threads so that they operate in parallel.

The process 400 is composed of three threads 410, 420, and 430. As the thread 410, a tester control section operates. As the thread 420, a tester control section 421 operates. As the thread 430, a hardware management section 431 operates. The threads 310, 320, and 330 can operate in parallel. Likewise, the threads 410, 420, and 430 can operate in parallel. A test plan 10 and a hardware use definition 20 are input to the process 300.

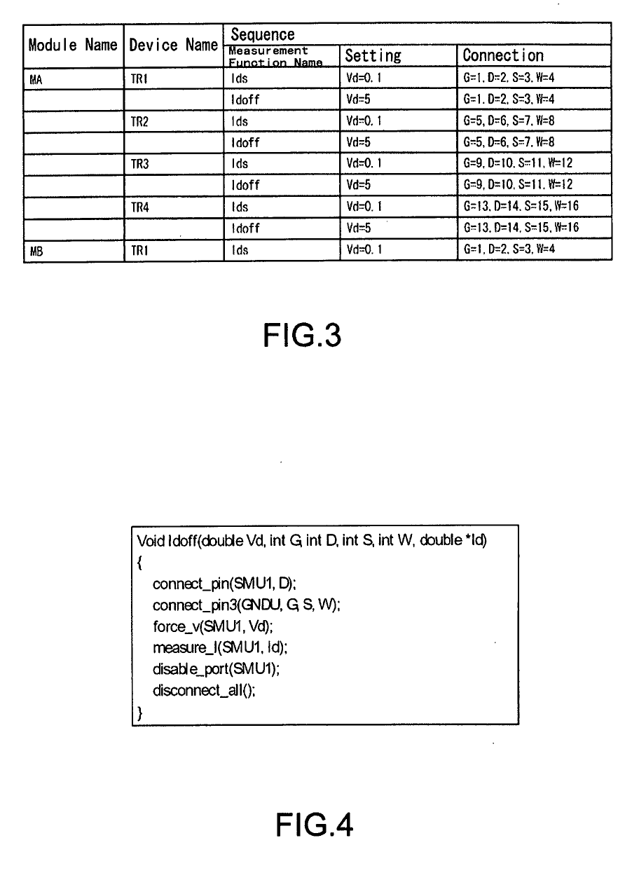

FIG. 3 shows a table of an example of the test plan 10. As shown in FIG. 3, a measurement function group for one device name in the test plan 10 is executed as sub sequences in parallel. In the test plan 10 shown in FIG. 3, two sequences (Ids and Idoff) preceded by device name TR1 are sub sequences for TR1. These sequences are followed by sub sequences for TR2, TR3, and TR4. As long as objects to be measured are physically independent, a plurality of sub sequences in a module can be executed in parallel. “Physically independent” denotes that pins connected by measurement functions of sub sequences of one object are not redundant in sub sequences of another object. Based on this criterion, it is determined that sub sequences for TR1, TR2, TR3, and TR4 shown in FIG. 3 be executable in parallel.

On the other hand, even if objects to be measured are physically independent, there is a case of which sub sequences cannot be executed in parallel. For example, in sub sequences of TR1 and TR2 shown in FIG. 3, although these sub sequences contain the execution of measurement function Idoff, when an SMU as a real hardware member is explicitly used, these measurement functions Idoff's cannot be executed in parallel. Thus, to allow these measurement functions Idoff's to be executed in parallel, with abstractive hardware names, the same SMUs are designated.

FIG. 4 shows an example of a program of measurement function Idoff called in the sequence shown in FIG. 3. Function connect_pin( ) or the like called in the program shown in FIG. 4 corresponds to a tester API shown in FIG. 2. The measurement function sections 322 and 332 designate an SMU that is an output measurement unit that composes the tester with an abstractive name.

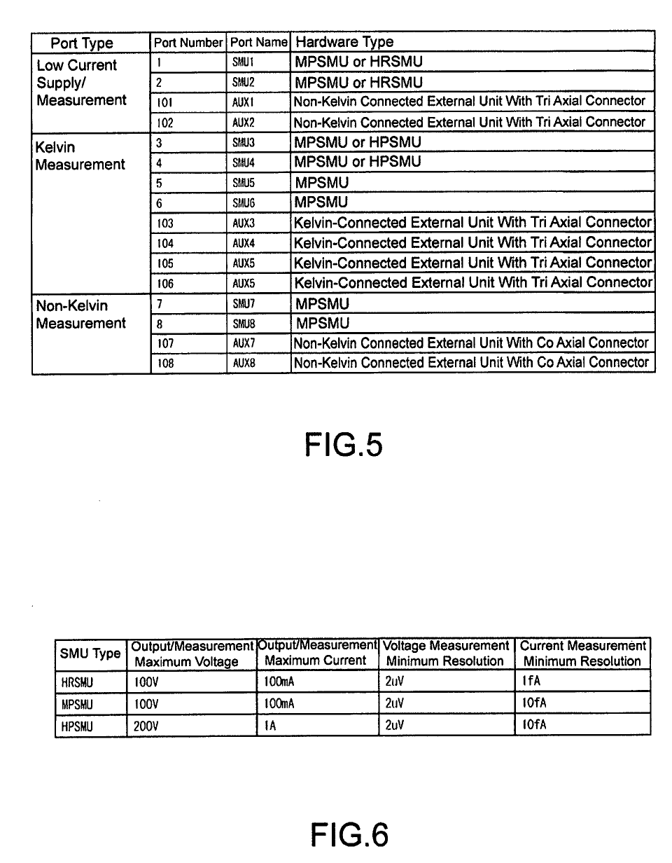

FIG. 5 shows a table of port types, port numbers, port names, and hardware types of the tester. A hardware member allocated to the tester is identified by a port number and a port name. The ports to which SMUs are connected have different features corresponding to port numbers. A low current supply/measurement port has high possibility of low current supply/measurement because of low path leakage current. A Kelvin measurement port provides high accuracy of voltage supply/measurement because of Kelvin connection.

FIG. 6 shows a table of types and measurement performances of SMUs contained in the tester. As shown in FIG. 6, as SMUs, there are MPSMU, HPSMU, and HRSMU. Since MPSMU or HRSMU is connected to the low current supply/measurement port, in the example shown in FIG. 4, when SMU1 is designated for connect_pin( ), it denotes that a pin is connected to an SMU or an HRSMU connected to the first port as the low current supply/measurement port.

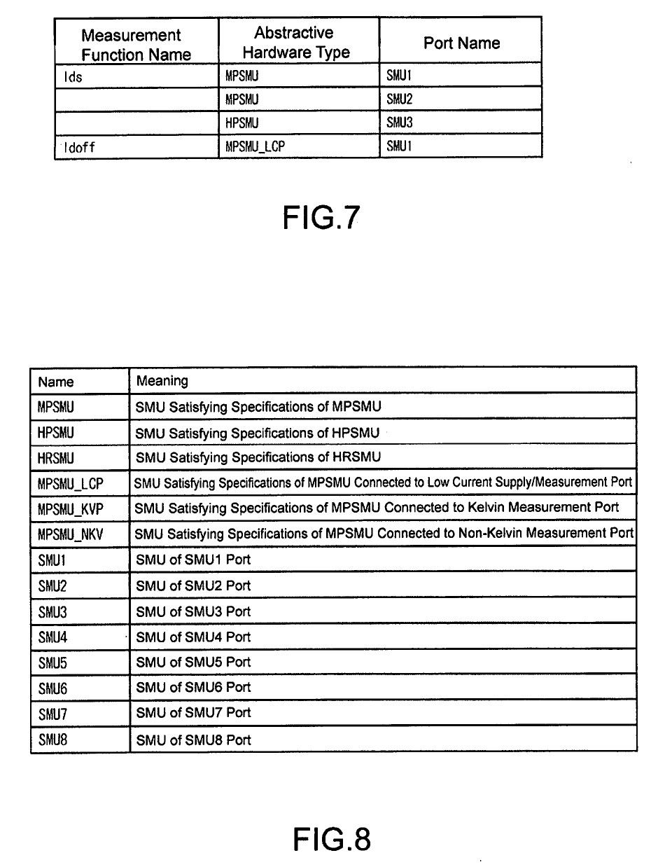

FIG. 7 shows a table of the hardware use definition 20 that is input to the process 300 together with the test plan 10. The hardware use definition 20 defines hardware types designated for an API call in a measurement function.

FIG. 8 shows a table of abstractive names and their meanings of measurement units used in the hardware use definition.

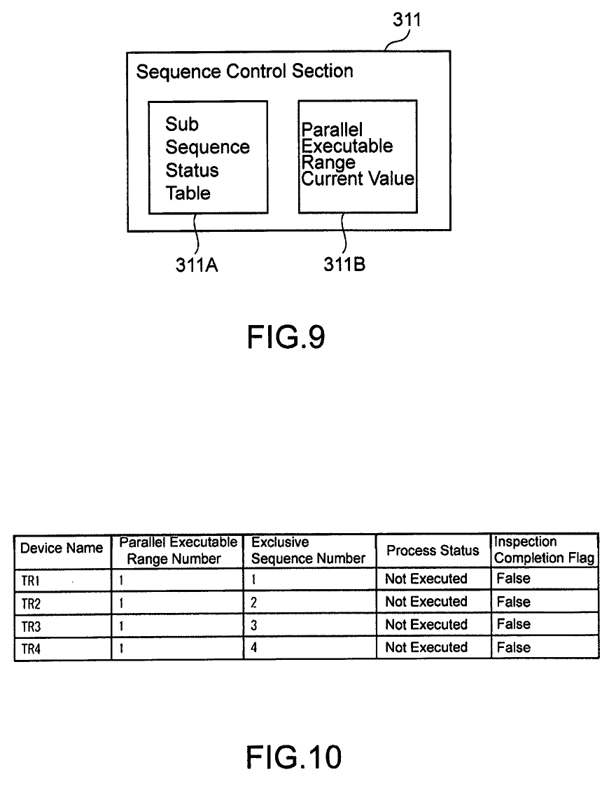

FIG. 9 is a schematic diagram showing information that the sequence control section 311 contains. As shown in the drawing, the sequence control section 311 has a sub sequence status table 311a and a parallel executable range current value 311b that contains a parallel executable range.

FIG. 10 shows a table of information that the sub sequence status table 311a contains.

The sub sequence status table contains a number starting with “1” that identifies a range of parallel executable sub sequence of each sub sequence of a module (hereinafter this number is referred to as a parallel executable range number), a number starting with “1” that identifies a sub sequence that is exclusively processed in the parallel executable range (hereinafter, this number is referred to as an exclusive sequence number), a process status of a sub sequence, and an inspection completion flag.

The sequence control section 311 checks sub sequences in the parallel executable range in the same module on the basis of connection information before executing the sequence of the module and assigns a unique parallel executable range number to each sub sequence. When the system is initialized, “1” is assigned to all sub sequences. When parallel executable range numbers are caused to be changed in the test plan, different numbers are assigned to sub sequences. On the other hand, sub sequences that cannot be executed in parallel are assigned the same exclusive sequence number in the parallel executable range. In FIG. 10, since TR1, TR2, TR3, and TR4 are not exclusively processed, different exclusive sequence numbers are assigned. There are three process statuses “not executed”, “executing”, and “executed”. When the table is initialized, the process status is “not executed”. The inspection completion flag is “true” or “false”. When the table is initialized, the inspection completion flag is “false”. The sequence control section 311 assigns “1” to the parallel executable range current value when the table is initialized.

The sequence control section 311 identifies sub sequences having the same parallel executable range number in the sub sequence status table on the basis of the parallel executable range current value. Thereafter, the sequence control section 311 identifies sub sequences to be executed on the basis of exclusive sequence number, process status, and inspection completion flag of sub sequences in the parallel executable range.

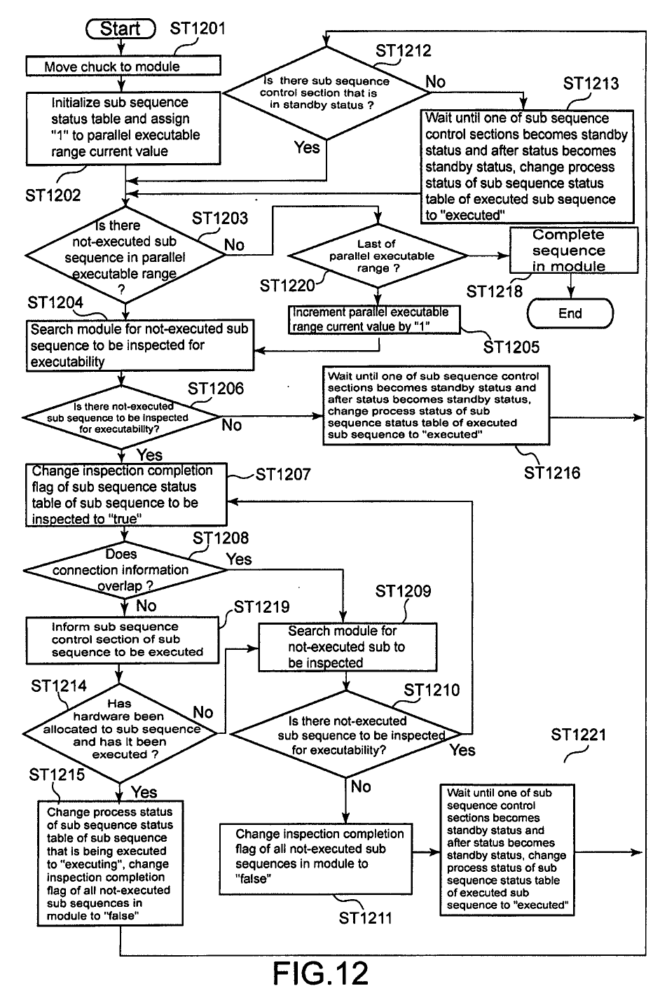

FIG. 12 is a flow chart showing the operation of the sub sequence process.

First of all, a chuck is moved to a module (at step ST1201). Thereafter, the sub sequence status table is initialized and “1” is assigned to the parallel executable range current value (at step ST1202). When there is a sub sequence in a parallel executable range that matches the parallel executable range current value (at step ST1203), the module is searched for a sub sequence to be inspected for executability (at step ST1204). When there is no not-executed sub sequence at step ST1203, it is determined whether or not the parallel executable range is the last of the module (at step ST1220). When the parallel executable range is the last of the module, it is determined that all the sequence of the module has been executed (at step ST1218) and the sub sequence process of the module is completed. In contrast, when the parallel executable range is not the last of the module, the parallel executable range current value is incremented by “1” (at step ST1205). Thereafter, the flow advances to step ST1204. At step ST1204, it is determined whether or not there is a not-executed sub sequence to be inspected for executability (at step ST1206). When there is no not-executed sub sequence to be inspected for executability, after one of the sub sequence control sections becomes “standby”, the process status of the sub sequence status table of the executed sub sequence is changed to “executed” (at step ST1216). Thereafter, the flow advances to step ST1212. In contrast, when there is a not-executed sub sequence to be inspected for executability, the inspection completion flag of the sub sequence status table of the sub sequence to be inspected is changed to “true” (at step ST1207). When the connection information of the sub sequence to be inspected is redundant with connection information of another sub sequence that is being executed (at step ST1208), the module is searched for a not-executed sub sequence to be inspected for executability (at step ST1209). When there is a not-executed sub sequence to be inspected for executability (at step ST1210), the flow advances to step ST1207. When there is no not-executed sub sequence to be inspected for executability (at step ST1210), the inspection completion flag of all the not-executed sub sequences of the module is changed to “false” (at step ST1211). After one of the sub sequence control sections that are being executed becomes “standby”, the process status of the sub sequence status table of the executed sub sequence is changed to “executed” (at step ST1221). Thereafter, the flow advances to step ST1212. When the connection information of the sub sequence to be inspected is not redundant with the connection information of another sub sequence that is being executed at step ST1208, the sub sequence control section is informed of a sub sequence to be executed (at step ST1219). When a hardware member is allocated to a sub sequence and it is executed (at step ST1214), the process status of the sub sequence status table of the sub sequence that is being executed is changed to “executing” and the inspection completion flag of all not-executed sub sequences is changed to “false” (at step ST1215). At step ST1212, it is determined whether or not there is a sub sequence control section that is in the standby status. When there is no sub sequence control section that is in the standby status, after one of the sub sequence control sections becomes “standby”, the process status of the sub sequence status table of the executed sub sequence is changed to “executed” (at step ST1213). When there is a sub sequence control section that is in the standby status, the flow advances to step ST1203.

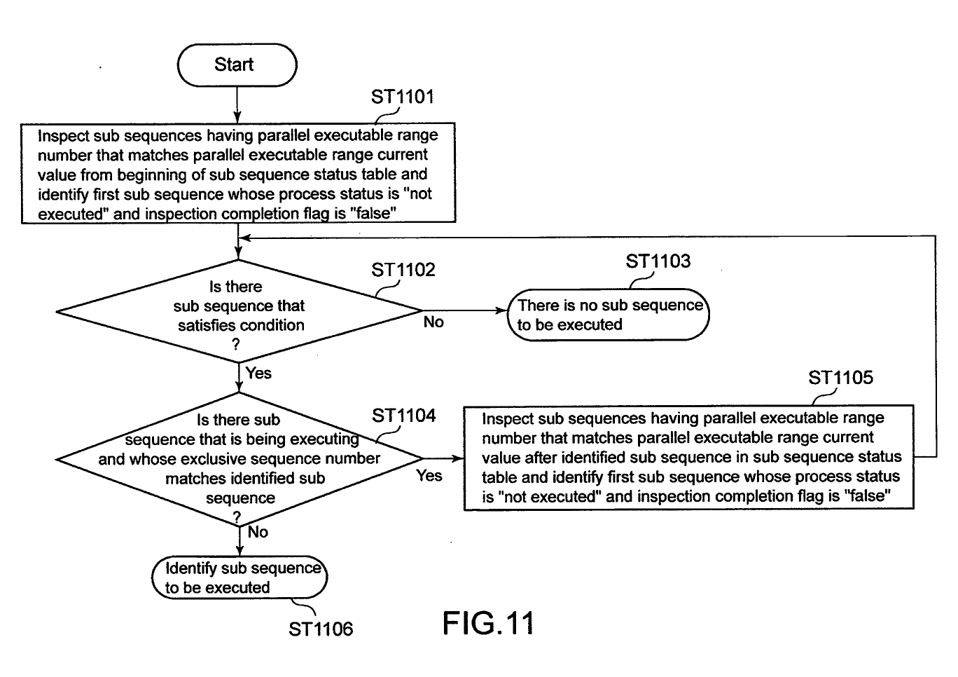

Next, step ST1204 and step ST1209 shown in FIG. 12 will be described in detail with reference to a flow chart shown in FIG. 11. FIG. 11 is a flow chart showing the operation that the sequence control section 311 performs to identify a not-executed sub sequence to be inspected for executability.

As shown in the drawing, sub sequences having a parallel executable range number that matches the parallel executable range current value in the sub sequence status table is inspected from the beginning of the table and a first sub sequence whose process status is “not executed” and whose inspection completion flag is “false” is identified (at step ST1101). When there is such a sub sequence (at step ST1102), it is determined that there be no not-executed sub sequence to be inspected for executability (at step ST1103). When there is a sub sequence that satisfies the condition (at step ST1102), the flow advances to step ST1104. At step ST1104, it is determined whether or not there is a sub sequence whose exclusive sub sequence number matches the exclusive sequence number of the identified sub sequence and that is being executed. When the determined result at step ST1104 is Yes, the flow advances to step ST1105. At step ST1105, a sub sequence having a parallel executable range number that matches the parallel executable range current value of the sub sequence status table is inspected after the identified sub sequence. A first sub sequence whose process status is “not executed” and whose inspection completion flag is “false” is identified (at step ST1105). Thereafter, the flow advances to step ST1102.

In contrast, when there is no sub sequence whose exclusive sub sequence number matches the exclusive sequence number of the identified sub sequence and that is being executed, a not-executed sub sequence to be executed for executability is identified (at step ST1106). As a result, the process of the flow chart shown in FIG. 11 is completed.

After all sub sequences have been executed, the same process is repeated for the next module.

In the following two cases, it may not be determined whether or not devices can be electrically measured in parallel on the basis of only connection information for measurement functions.

### <First Case>

Devices share a substrate or well and they are electrically connected, but not explicitly connected through wires.

### <Second Case>

Although devices are designed to be electrically insulated, their measurements mutually interfere due to other than a device structure such as a probe card.

According to an embodiment of the present invention, a parallel test attribute can be designated for a device name of the test plan 10. The tester can be informed of restrictions for execution of parallel tests.

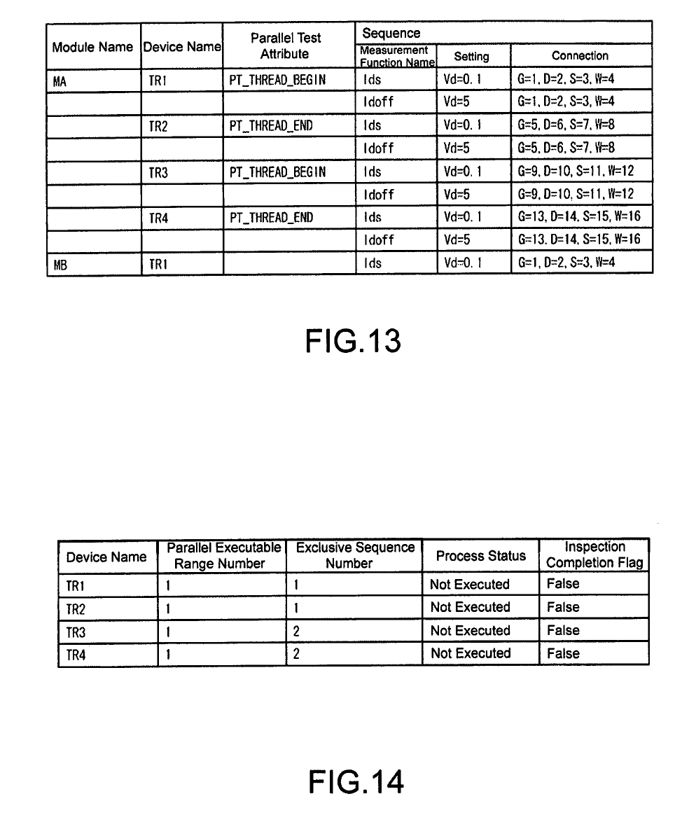

FIG. 13 shows a table of the test plan 10 that allows a parallel test attribute to be designated. In FIG. 13, “PT_THREAD_BEGIN” and “PT_THREAD_END” attributes are used for the <first case>. With the attributes designated, sub sequences for devices surrounded by BEGIN and END are caused to be executed exclusively (not in parallel). In the example shown in FIG. 13, it is supposed that devices TR1 and TR2 share a well and devices TR3 and TR4 share a substrate. In this case, sub sequences of TR1 and TR2 and those of TR3 and TR4 can be executed in parallel.

FIG. 14 shows a sub sequence status table for the sequence shown in FIG. 13. As shown in FIG. 14, the table is initialized so that a common exclusive sequence number is assigned to sub sequences surrounded by “PT_THREAD_BEGIN” and “PT_THREAD_END”. When the process of the sequence is executed according to the flow charts shown in FIG. 11 and FIG. 12 on the basis of the sub sequence status table, sub sequences of TR1 and TR2 and those of TR3 and TR4 can be executed in parallel.

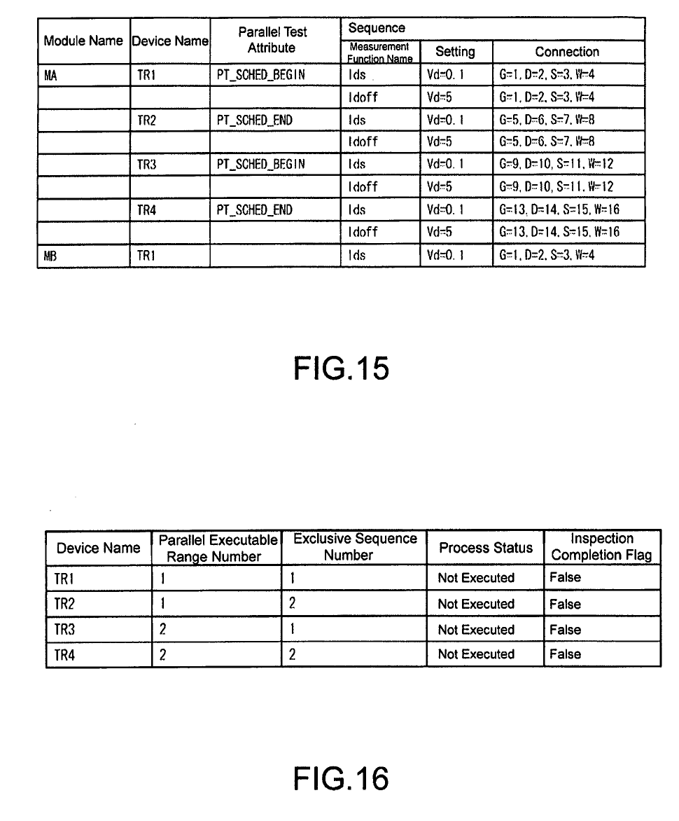

FIG. 15 shows a table of a test plan describing parallel test attribute used in the case that although devices are designed to be electrically insulated, they mutually interfere due to other than a device structure such as a probe card. As shown in FIG. 15, only sub sequences of devices surrounded by “PT_SCHED_BEGIN” and “PT_SCHED_END” are caused to be executed in parallel. In the example shown in FIG. 15, it is assumed that when sub sequences of TR1 and TR2 are executed in parallel, measurements are able to be normally performed and when sub sequences of TR3 and TR4 are executed in parallel, measurements are able to be normally performed. However, it is assumed that when sub sequences of TR1 and TR2 and those of TR3 or TR4 are executed in parallel, since they mutually interfere, measurements cannot be normally performed. This attribute is provided to prohibit such sub sequences from being executed in parallel.

FIG. 16 shows a sub sequence status table for the test plan shown in FIG. 15. As shown in FIG. 16, the sub sequence status table is initialized so that sub sequences surrounded by “PT_SCHED_BEGIN” and “PT_SCED_END” are assigned different parallel executable range numbers. When the sequence is processed according to the flow charts shown in FIG. 11 and FIG. 12 based on the sub sequence status table, sub sequences of TR1 and TR2 are executed in parallel. When this sequence is executed, sub sequences of TR3 and TR4 can be executed in parallel.

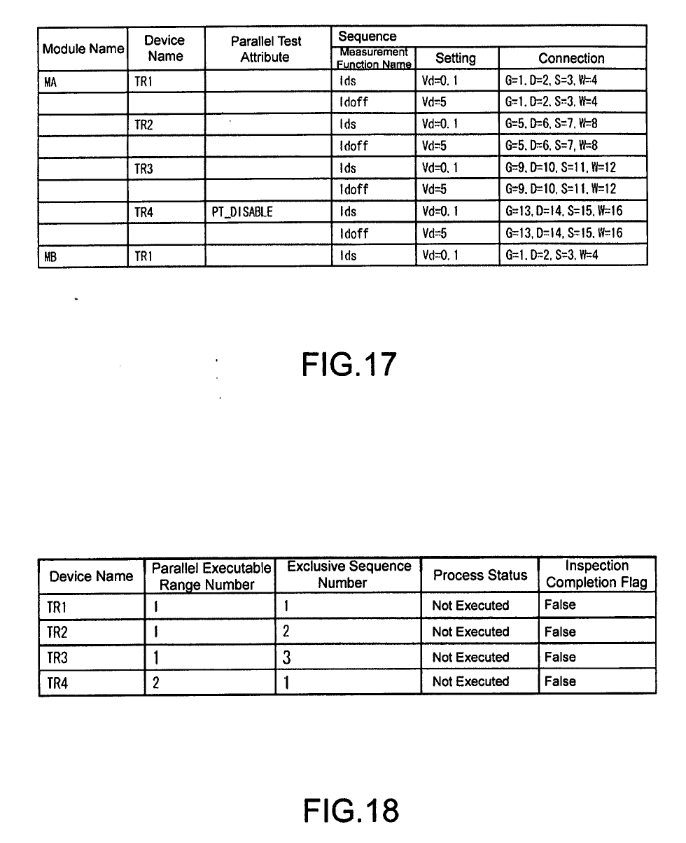

FIG. 17 shows a table of a test plan describing an attribute that denotes that a sub sequence of a device is not able to be executed when a designated sub sequence of a designated device is executed. As shown in FIG. 17, device TR4 has a parallel test attribute “PT_DISABLE” used for the foregoing <second case>. In this example, it is assumed that since Idoff of device TR4 measures a fine current, other measurements that interfere with the current measurement are suppressed.

FIG. 18 shows a sub sequence status table for the test plan shown in FIG. 17. As shown in FIG. 18, the table is initialized so that a sub sequence having “PT_DISABLE” is assigned a parallel executable range number different from those of the preceding and following sub sequences. When the sequence is processed according to the flow chart shown in FIG. 11 and FIG. 12 on the basis of the sub sequence status table, after sub sequences of TR1, TR2, and TR3 are executed in parallel, a sub sequence of TR4 can be independently executed.

In the process shown in FIG. 12, the sequence control section 311 designates a sub sequence and causes the sub sequencer control sections 321 and 331 to execute it.

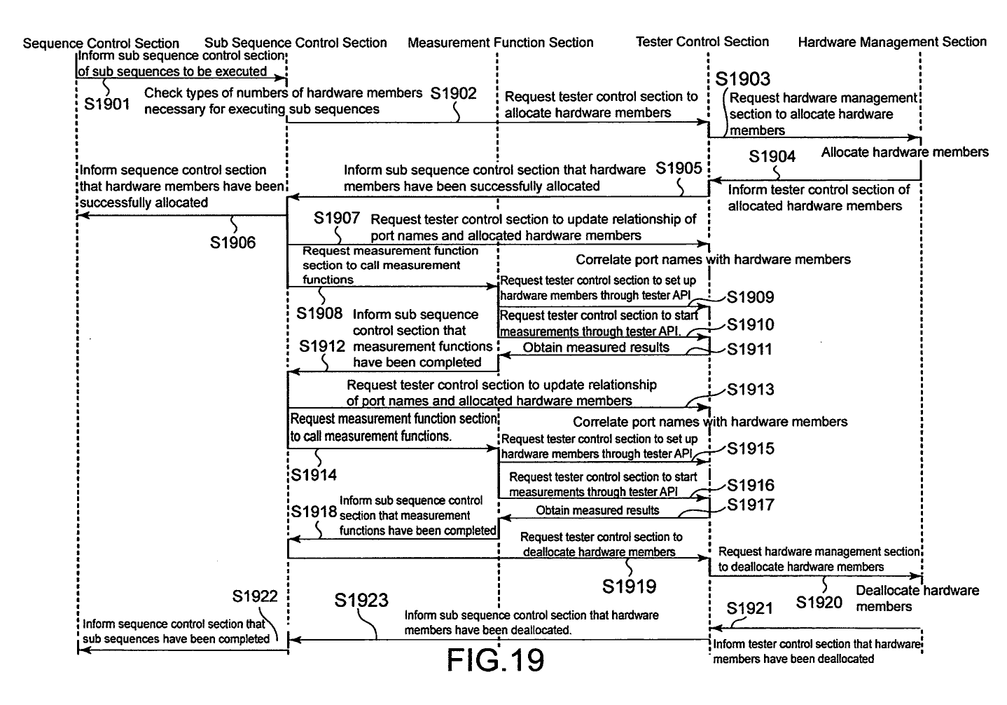

FIG. 19 is a sequence chart that represents signal handing in the case that sub sequences are executed. As shown in FIG. 19, the sequence control section informs a sub sequence control section of sub sequences to be executed (at sequence S1901). The sub sequence control section checks the types and number of hardware members necessary for executing the sub sequences. The sub sequence control section requests the tester control section to allocate hardware members (at sequence S1902) and the tester control section requests the hardware management section to allocate hardware members (at sequence S1903). The hardware management section allocates hardware members and informs the tester control section of the allocated hardware members (at sequence S1904). The tester control section informs the sub sequence control section that hardware members have been successfully allocated (at sequence S1905). The sub sequence control section informs the sequence control section that hardware members have been successfully allocated (at sequence S1906). Thereafter, the sub sequence control section requests the tester control section to update the relationship of port names and the allocated hardware members (at sequence S1907) and the tester control section correlates the port names with the hardware members. Thereafter, the sub sequence control section requests the measurement function section to call measurement functions (at sequence S1908) and the measurement function section requests the tester control section to set up hardware members through the tester API (at sequence S1909) and requests the tester control section to start measurements through the tester API (at sequence S1910). The measurement function section obtains measured results from the tester control section (at sequence S1911) and informs the sequence control section that the measurement functions have been completed (at sequence S1912). The contents of sequence S1913 to sequence S1918 are the same as those from sequence S1907 to sequence S1912, their description will be omitted. Thereafter, the sub sequence control section requests the tester control section to deallocate the hardware members (at sequence S1919). The tester control section requests the hardware management section to deallocate the hardware members (at sequence S1920). The hardware management section deallocates the hardware members. Thereafter, the hardware management section informs the tester control section that the hardware members have been deallocated (at sequence S1921), the tester control section informs the sub sequence control section that the hardware members have been deallocated (at sequence S1923), and the sub sequence control section informs the sequence control section that the sub sequences have been completed (at sequence S1922).

In other words, the sub sequencer control sections 321 and 331 that have been requested from the sequence control section 311 identifies measurement functions that are executed in sub sequences on the basis of a test plan and creates a list of types of abstractive hardware members necessary for executing the measurement functions on the basis of the hardware use definition. The sub sequencer control sections 321 and 331 supply the list to the hardware management section 431 through the tester control sections 411 and 421 and allocates real hardware members that the hardware management section 431 has requested. When the hardware management section 431 has successfully allocated the real hardware members, the hardware management section 431 informs the tester control sections 411 and 421 of the allocated real hardware members. The sub sequence control sections 321 and 331 determines that the real hardware members necessary for executing all the measurement functions in the sub sequences have been obtained and execute the measurement functions. Whenever the sub sequencer control sections 321 and 331 execute a measurement function, they supply a list of the port names and types of abstractive hardware members to the tester control sections 411 and 421, causes them to update the relationship of real hardware members and port names, and execute the measurement functions.

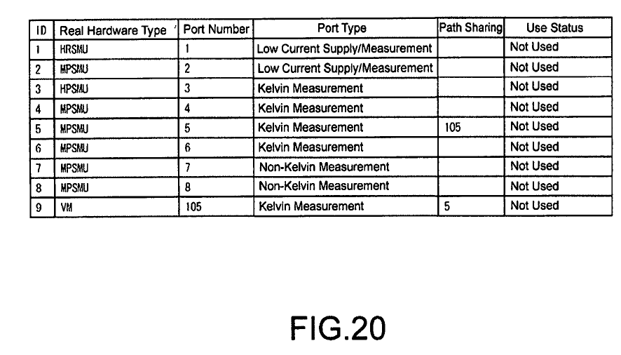

FIG. 20 shows a hardware management table contained in the hardware management section 431. The hardware management table is used to manage individual hardware members of the tester. As shown in FIG. 20, the hardware management table contains a hardware ID, a real hardware type, a port number, a port type, path sharing information, and use statue of each hardware member. When the tester is started up, the hardware management table is initialized so that these values match the hardware structure and status of the tester.

The “ID” is assigned a unique number corresponding to each real hardware member. The tester control sections 411 and 421 can identify a real hardware member by the same ID. The “path sharing” represents an ID of a hardware member that shares a path from the hardware member to a probe pin. The “use status” has two types of “used” and “using”. In the example shown in FIG. 20, as an external unit that is Kelvin connected with a Tri axial connector, a volt meter (VM) is connected to port 105 (AUX5). It is assumed that the maximum measurement voltage of this volt meter is 100 V and the measurement voltage resolution thereof is 1 uV. Port 105 and port 5 share a path.

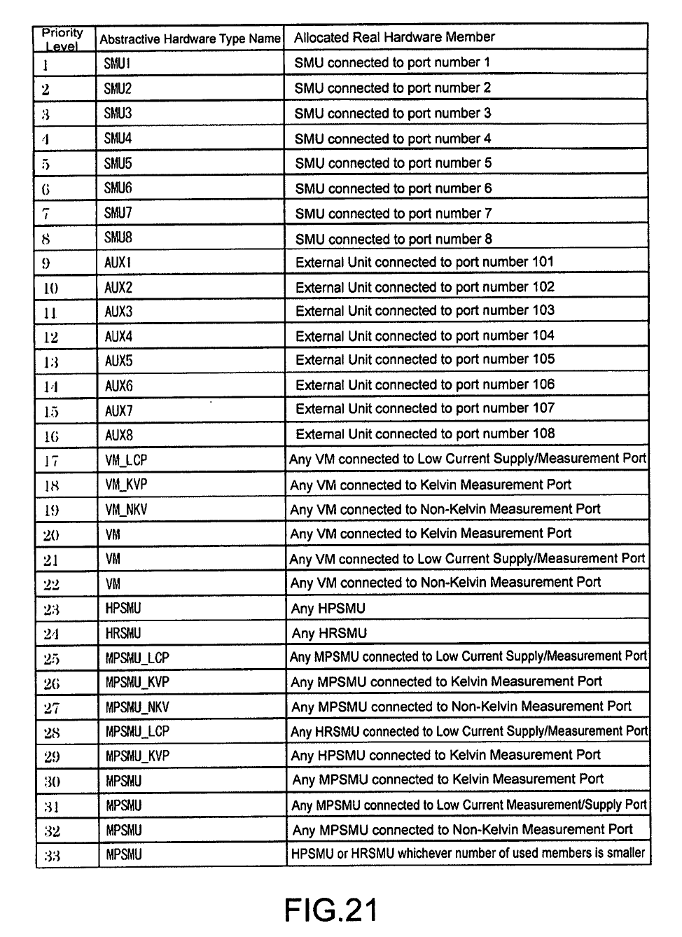

In the hardware allocation process, the hardware management section 431 preferentially allocates hardware members that are difficult to be substituted with other hardware members for abstractive hardware types in the hardware use definition. In this method, the hardware management section 431 preferentially allocates hardware members that are not substituted with other hardware members. Thus, substitutable hardware members can be prevented from being allocated before non-substitutable hardware members are allocated. For example, HPSMU is assigned priority level 23 and MPSMU is assigned priority level 33 as shown in FIG. 21. In the hardware allocation process, when a plurality of real hardware members are able to be assigned to abstractive hardware types in the hardware use definition, hardware members that are substitutable are preferentially allocated. In this method, since hardware members that are not substitutable are allocated for later sub sequences, many sequences can be executed in parallel as with MPSMU having priority levels 30 to 33 shown in FIG. 21.

FIG. 21 shows a table of types of real hardware members that the hardware management section allocates to abstractive hardware type names and their priority levels. In this specification, this table is hereinafter referred to as the hardware allocation priority level table. In this table, type names and priority levels of combinations or structures that can exist as real hardware members of combinations of port types and measurement unit types of for example SMUs or voltage meters or the like are defined.

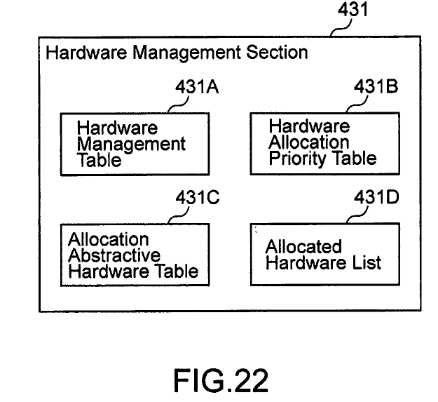

FIG. 22 is a schematic diagram showing information that the hardware management section 431 contains. As shown in FIG. 22, the hardware management section 431 contains a hardware management table 431a, a hardware allocation priority table 431b, an allocation abstractive hardware table 431c, and an allocated hardware list 431d.

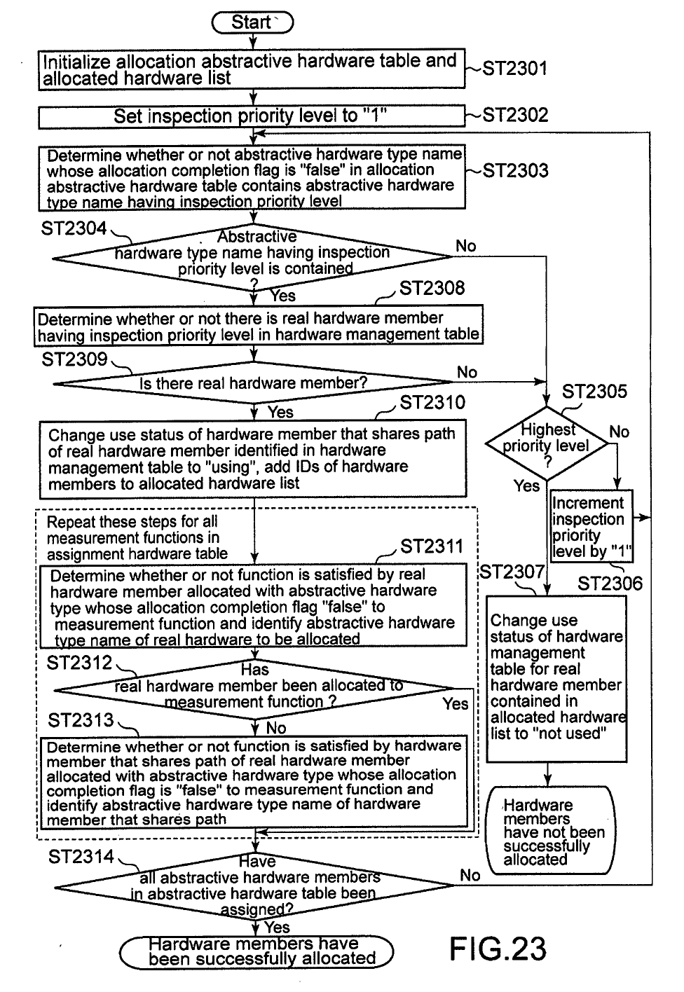

FIG. 23 is a flow chart showing the operation of the hardware management section 431 that allocates real hardware members. As shown in FIG. 23, the allocation abstractive hardware table 431c and the allocated hardware list 431d are initialized (at step ST2301). Thereafter, the inspection priority level is set to “1” (at step ST2302) and it is determined whether or not an abstractive hardware type name whose allocation completion flag is “false” in the allocation abstractive hardware table 431c contains an abstractive hardware type name having an inspection priority level (at step ST2303). When an abstractive hardware type name having an inspection priority level is not contained (at step ST2304), it is determined whether or not the priority level is the highest (at step ST2305). When the priority level is not the highest, the inspection priority level is incremented by “1” (at step ST2306). Thereafter, the flow advances to step ST2302. When the priority level at step ST2305 is the highest, the use status of the hardware management table 431a for the real hardware member contained in the allocated hardware list 431d is changed to “not used” (at step ST2307). In this case, since the hardware member has failed to be allocated, the process is terminated.

In contrast, when an abstractive hardware type name having an inspection priority level is contained at step ST2304, it is determined whether or not there is a real hardware member having the inspection priority level in the hardware management table 431a (at step ST2308). When there is no real hardware member (at step ST2309), the flow advances to step ST2305. When there is a real hardware member (at step ST2309), the use status of a hardware member that shares the path with the real hardware member identified in the hardware management table 431a is changed to “using” and the IDs of the hardware members are added to the allocated hardware list (at step ST2310). Thereafter, it is determined whether or not the function is satisfied by the real hardware member allocated with the abstractive hardware type whose allocation completion flag is “false” to the measurement function and thereby an abstractive hardware type of a real hardware member to be allocated is identified. When a plurality of abstractive hardware types in the measurement function satisfy the condition, the real hardware member is allocated to a hardware type name having a higher priority level. Thereafter, the allocation completion flag of the allocated abstractive hardware type in the allocation abstractive hardware table 431c is changed to “true” (at step ST2311). When a real hardware member has not been assigned to the measurement function (at step ST2312), it is determined whether or not the function is satisfied by a hardware member that shares the path with the real hardware member assigned with an abstractive hardware type whose allocation completion flag is “false” to the measurement function and thereby an abstractive hardware type name of a hardware member that shares the path and that is allocated is identified. When a plurality of abstractive hardware types of the measurement function satisfy the condition, the real hardware member is allocated to an abstractive hardware type name having a higher priority level. The allocation completion flag of the allocated abstractive hardware type in the allocation abstractive hardware table 431c is changed to “true” (at step ST2313). When it is determined that all abstractive hardware types have been allocated in the allocation abstractive hardware table with the allocation completion flag (at step ST2314), since the hardware member has been successfully allocated, the process is completed. Unless the hardware member has not been allocated, the flow advances to step ST2303.

When a real hardware member has been allocated to the measurement function at step ST2312, the flow advances to step ST2314. Step ST2311 to step ST2313 are repeated for all measurement functions in the allocation abstractive hardware table.

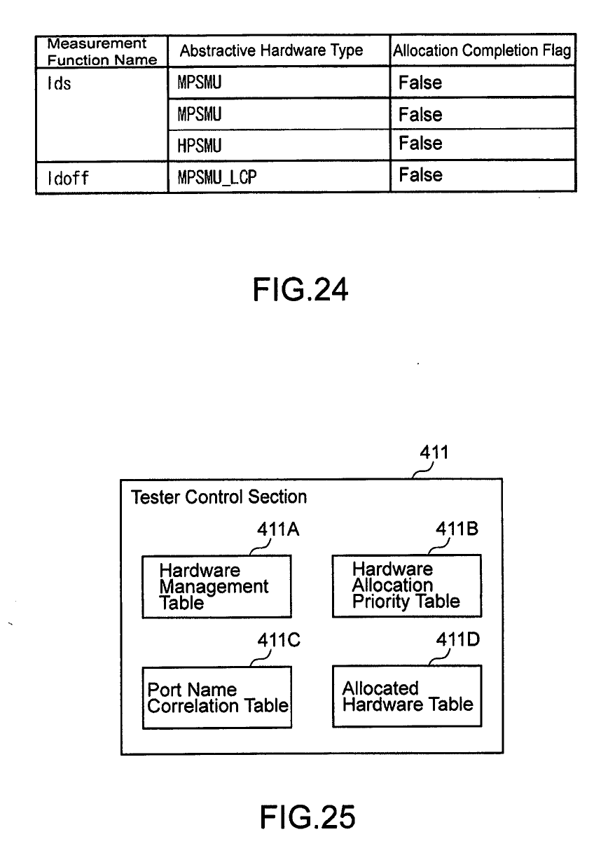

FIG. 24 shows the allocation abstractive hardware table 431c. As shown in FIG. 24, the allocation abstractive hardware table 431c contains a measurement function name contained in a sub sequence, an abstractive hardware type necessary for executing a measurement function, and an allocation completion flag indicating whether or not a hardware member has been allocated. The allocation abstractive hardware table 431c is initialized based on a list of abstractive hardware members necessary for measurement functions in sub sequences. The list is supplied from the sub sequencer control sections 321 ad 331 through the tester control sections 411 and 421 and the allocation completion flag of each abstractive hardware type is initialized to “false”.

The allocated hardware list 431d shown in FIG. 22 is a list of IDs assigned to individual hardware members in the hardware management table.

FIG. 25 schematically shows information that the tester control section 411 (or 421) contains.

As shown in FIG. 22, the tester control section 411 contains a hardware management table 411a, a hardware allocation priority table 411b, a port name correlation table 411c, and an allocated hardware table 411d. The hardware management table 411a and the hardware allocation priority table 411b are the same as those that the hardware management section 431 contains. The allocated hardware table 411d is a table that contains a hardware ID and a correlation completion flag. This table is initialized based on the list of allocated hardware members supplied from the hardware management section 431.

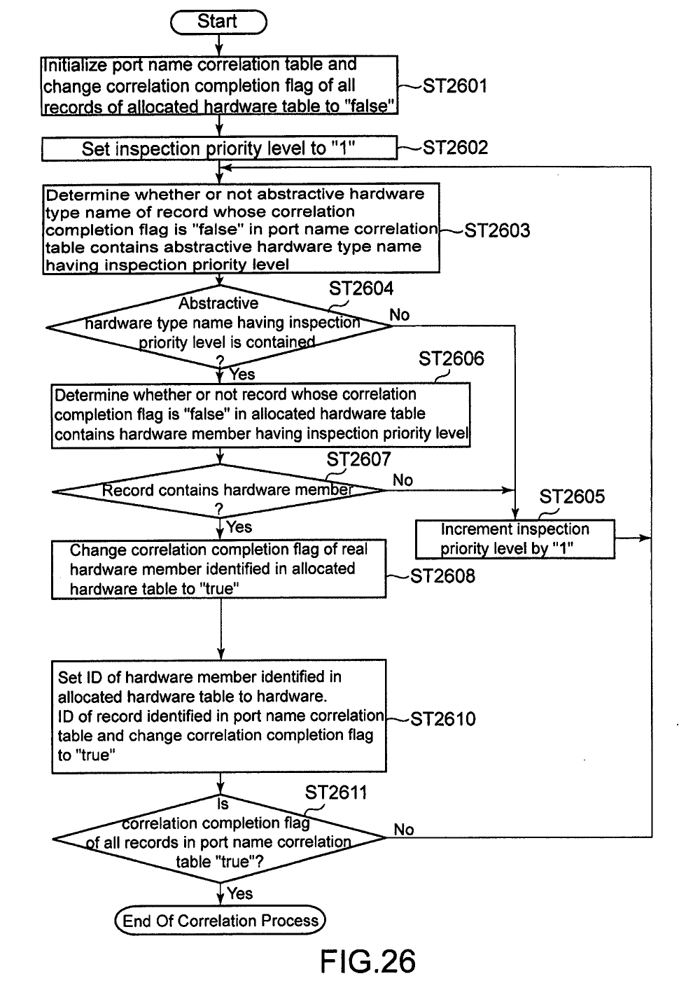

FIG. 26 is a flow chart showing a process that the tester control section 411 performs to correlate a part name of a measurement function with a hardware member. As shown in FIG. 26, the port name correlation table is initialized and the correlation completion flag of all records in the allocated hardware table is changed to “false” (at step ST2601). Thereafter, the inspection priority level is set to “1” (at step ST2602). It is determined whether or not the abstractive hardware type name of a record whose correlation completion flag is “false” in the port name correlation table contains an abstractive hardware type name having an inspection priority level (at step ST2603). When an abstractive hardware type name having an inspection priority level is not contained (at step ST2604), the inspection priority level is incremented by “1” (at step ST2605). Thereafter, the flow advances to step ST2603.

When an abstractive hardware type name having an inspection priority level is contained at step ST2604, it is determined whether or not a hardware member having an inspection priority level is in a record whose correlation completion flag is “false” in the allocated hardware table (at step ST2606). When there is no hardware member (at step ST2607), the flow advances to step ST2605.

When there is a hardware member at step ST2607, the correlation completion flag of the identified record in the allocated hardware table is changed to “true” (at step ST2608). The hardware ID identified in the allocated hardware table is set to the hardware ID of the identified record in the port name correlation table and the correlation completion flag is changed to “true” (at step ST2601). When the correlation completion flag of all records in the port name correlation table is not “true” (at step ST2611), the flow advances to step ST2603. When the correlation completion flag of all the records is “true” (at step ST2611), the correlation process is completed.

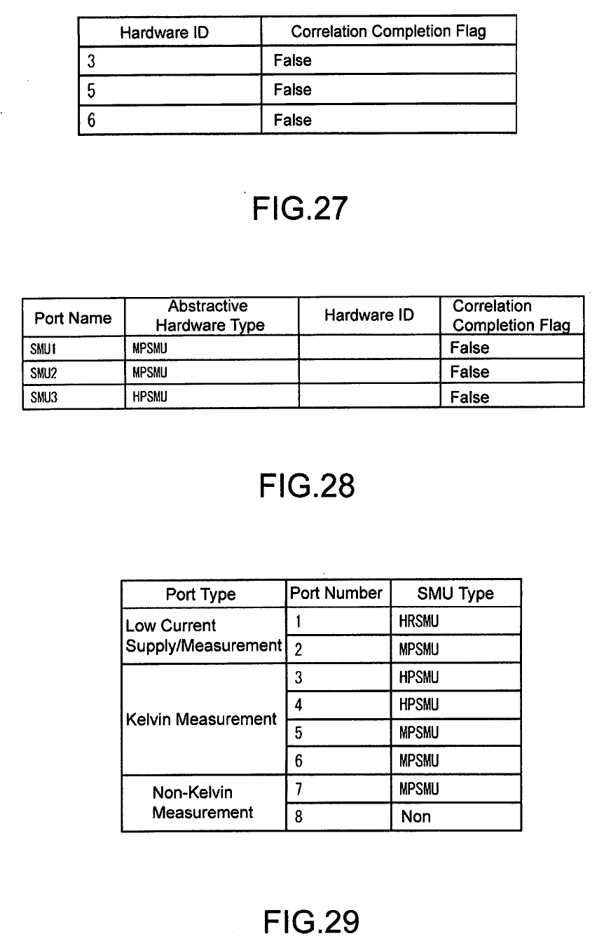

FIG. 27 shows the allocated hardware table 411d. When the allocated hardware table 411d is initialized, the correlation completion flag of all records is changed to “false”.

FIG. 28 shows the port name correlation table 411c. The port name correlation table 411c is initialized based on a table that correlates port names for measurement functions with abstractive hardware types. This table is supplied when the tester control section 411 is requested by the sub sequence control section to update the relationship of port names and allocated hardware members. When the port name correlation table 411c is initialized, the hardware ID of all records is set to an invalid value and the correlation completion flag of all records is changed to “false”. In the process shown in FIG. 26, all port names are correlated with hardware IDs.

After the port names and real hardware members are correlated, the sub sequence control section calls measurement functions. The measurement function section supplies port names to the tester API and causes the tester control section to control hardware members. The tester control section identifies a hardware member by the port name on the basis of the port name correlation table and controls the hardware member through the tester API.

Next, an example of which the semiconductor parametric test system executes sub sequences in parallel will be described.

FIG. 29 shows a table representing the structure of the tester used in this example. It is assumed that sub sequences are executed in parallel in this tester structure on the basis of the hardware use definition shown in FIG. 7. In this system, there are three threads of the sub sequence control sections and the tester control sections. It is thought that the execution of a measurement function in a sub sequence takes a predetermined time.

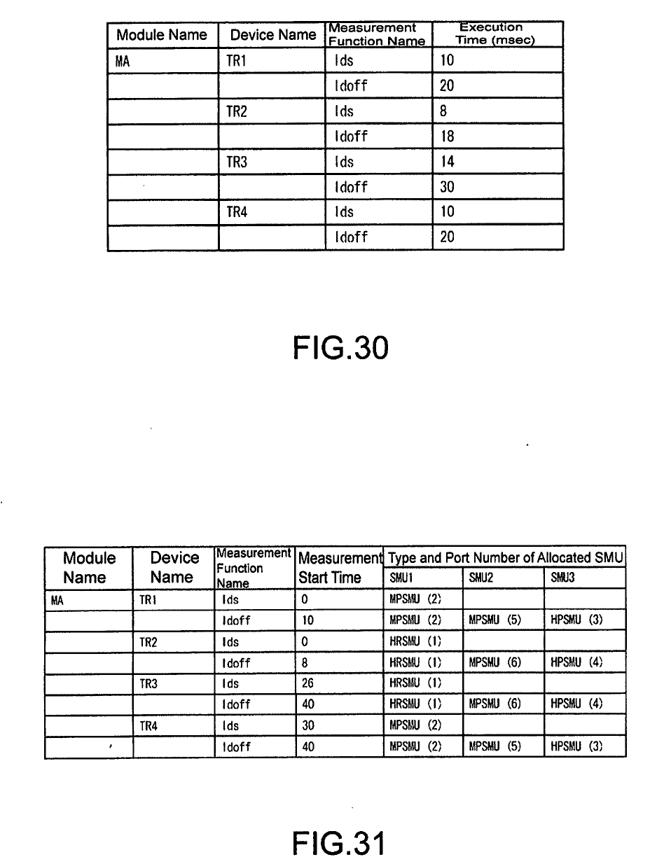

FIG. 30 shows a table of assumed execution times of measurement functions in sub sequences. It is assumed that times other than execution times of measurement functions are so small that they are able to be ignored.

FIG. 31 shows a table of execution results of sub sequences. As shown in the table, it is clear that a sub sequence is executed at a measurement start time (represented by an elapsed time after the module has been moved) and hardware members are properly allocated to SMU1, SMU2, and SMU3.

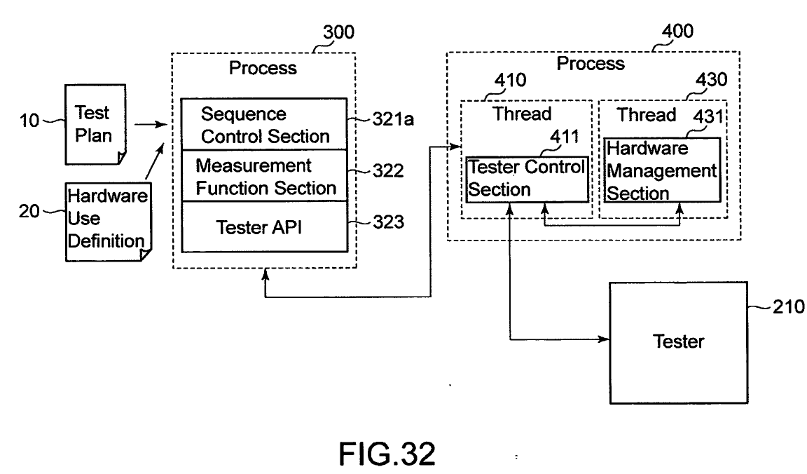

FIG. 32 is a schematic diagram showing the structure of a semiconductor parametric test system according to another embodiment of the present invention.

In FIG. 32, for simplicity, similar portions to those in FIG. 2 are denoted by similar reference numerals and their description will be omitted. A sequence control section 321a corresponds to the sub sequencer control section 321 shown in FIG. 2.

When a tester API call using a port name in a measurement function uniquely identifies a hardware member of a tester, it may become inconvenient since the same measurement function is not able to be used in testers having different structures. When a hardware member used in a measurement function is specifically described, although it may operate in one system, it may not operate in other systems. For example, when a measurement function describes an SMU connected to port number 1, although it operates in a system of which an SMU is connected to port 1, the same program does not operate in the case that the same SMU is connected to another port.

On the other hand, when an SMU equivalent to an MPSMU that is a low current supply/measurement port is abstractively designated as an SMU used for a measurement function, as long as such an SMU is connected to another port, it is able to be used. The semiconductor parametric test system is able to be used for another system without need to rewrite the program.

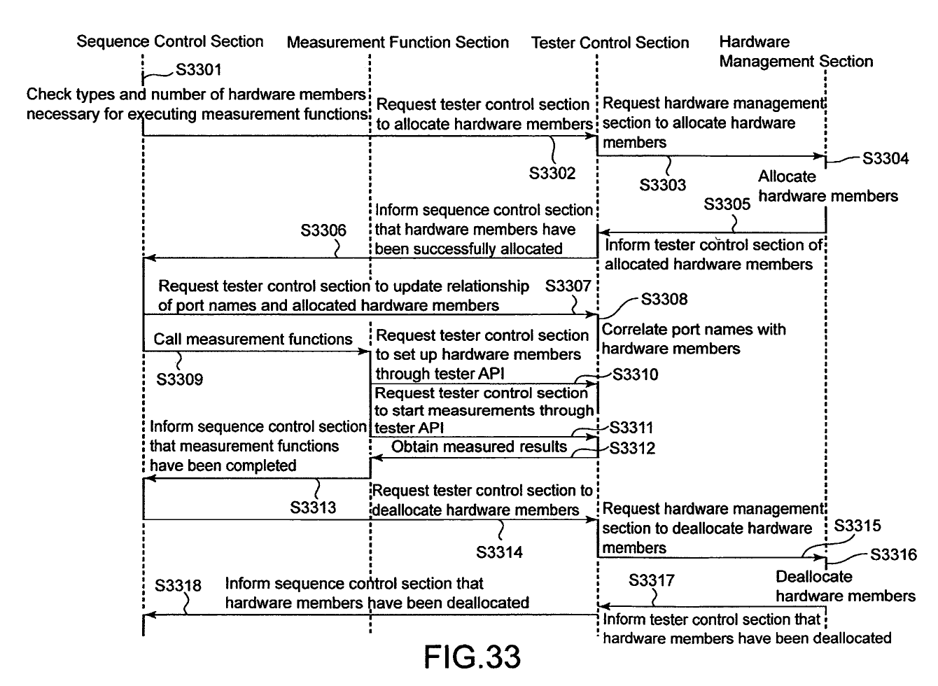

FIG. 33 is a sequence chart showing the operation of the semiconductor parametric test system according to the embodiment having the structure shown in FIG. 32.

First, the sequence control section checks the types and the number of hardware members necessary for executing measurement functions (at sequence S3301). Thereafter, the sequence control section requests the tester control section to allocate hardware members (at sequence S3302). Thereafter, the tester control section requests the hardware management section to allocate hardware members (at sequence S3303). The hardware management section allocates hardware members (at sequence S3304) and informs the tester control section of the allocated hardware members (at sequence S3305). Thereafter, the tester control section informs the sequence control section that hardware members have been successfully allocated (at sequence S3306). Thereafter, the sequence control section requests the tester control section to update the relationship of port names and the allocated hardware members (at sequence S3307). The tester control section correlates the port names and the hardware members (at sequence S3308). Thereafter, the sequence control section calls a measurement function (at sequence S3309). The measurement function section requests the tester control section to set up hardware members through the tester API (at sequence S3310) and to start measurements through the tester API (at sequence S3311). Thereafter, the measurement function section obtains measured results from the tester control section (at sequence S3312) and informs the sequence control section that the measurement functions have been completed (at sequence S3313). The sequence control section requests the tester control section to deallocate hardware members (at sequence S3314), the tester control section requests the hardware management section to deallocate hardware members (at sequence S3315), and the hardware management section deallocates hardware members. Thereafter, the tester control section informs the sequence control section that hardware members have been deallocated (at sequence S3318).

Although the present invention has been shown and described with respect to a best mode embodiment thereof, it should be understood by those skilled in the art that the foregoing and various other changes, omissions, and additions in the form and detail thereof may be made therein without departing from the spirit and scope of the present invention.

What is claimed is:

1. An apparatus of measuring characteristics of a plurality of semiconductor devices with a plurality of measurement units, the apparatus comprising:
parallel measurement executability determination means for identifying sets of a semiconductor device and a measurement function, which are able to be measured in parallel based on connection information of the semiconductor devices; and
a plurality of measurement function sections which use a first abstractive name which abstractively identifies the plurality of measurement units for the sets of the measurement function and the semiconductor device which are able to be measured in parallel by the parallel measurement executability determination means.

2. The apparatus as set forth in claim 1, further comprising:
measurement unit allocation means, having measurement unit information containing a second abstractive name which abstractively identifies the plurality of measurement units, for allocating an abstractively identified measurement unit for the set of the semiconductor device and the measurement function, which are able to be measured in parallel by the parallel measurement executability determination means, to the measurement function.

3. The apparatus as set forth in claim 2,
wherein the measurement unit information correlatively contains the second abstractive name which abstractively identifies the plurality of measurement units and priority levels based on which the plurality of measurement units are allocated to measurement functions, and
wherein the measurement unit allocation means allocates the abstractively identified measurement units to the measurement functions in the order of higher priority levels.

4. The apparatus as set forth in claim 3,
wherein when there are a plurality of measurement units allocatable to the second abstractive name, the priority levels are assigned lower values in proportion to non-substitutability of the measurement units, and
wherein when there are a plurality of the second abstractive names that are able to identify a measurement unit, the priority levels of the second abstractive names are assigned higher values in proportion to non-substitutability of the measurement units.

5. The apparatus as set forth in claim 1,
wherein the plurality of measurement function sections operate in parallel.

6. The apparatus as set forth in claim 1, further comprising:
parallel test attribute input means for inputting a parallel test attribute,
wherein when information which permits a predetermined set of the semiconductor devices to be measured in parallel is input to the parallel attribute input means, the parallel measurement executability determination section determines whether or not the predetermined set is able to be measured in parallel.

7. The apparatus as set forth claim 1, further comprising:
parallel test attribute input means for inputting a parallel test attribute,
wherein when information which does not permit a predetermined set of the semiconductor devices to be measured in parallel is input to the parallel attribute input means, the parallel measurement executability determination means determines whether or not the other than the predetermined set is able to be measured in parallel.

8. The apparatus as set forth in claim 1, further comprising:
parallel test attribute input means for inputting a parallel test attribute,
wherein when information which denotes that a predetermined semiconductor device of the semiconductor devices is not able to be measured in parallel is input to the parallel test attribute input means, the parallel measurement executability determination means determines whether or not other than the predetermined semiconductor device is able to be measured in parallel.

9. An apparatus of executing a measurement function for a semiconductor device with a plurality of measurement units and measuring characteristics of the semiconductor device, the apparatus comprising:
measurement allocation portion, having measurement unit information containing abstractive names which abstractively identify the measurement units, for allocating abstractively identified measurement units of a set of semiconductor devices and measurement functions to the measurement functions.
